(19) United States
(12) Patent Application Publication
(10) Pub. No.: US 2026/0235962 A1
(43) Pub. Date: Aug. 13, 2026

(54) GAS SUPPLY MODULE, FLUID HANDLING SYSTEM, LITHOGRAPHIC APPARATUS AND DEVICE MANUFACTURING METHOD

(71) Applicant: ASML NETHERLANDS B.V., Veldhoven (NL)

(72) Inventors: Maarten HOLTRUST, Eindhoven (NL); Seyed Armin RAZAVIEH, Eindhoven (NL); Leonarda Hendrika VAN DEN HEUVEL, Mariahout (NL); Marc Léon VAN DER GAAG, Rheden (NL)

(21) Appl. No.: 19/155,835

(22) PCT Filed: Jan. 15, 2024
(86) PCT No.: PCT/EP2024/050822

§ 371 Date: Aug. 12, 2025

(30) Foreign Application Priority Data
Feb. 13, 2023 (EP) 23156328.9

(51) Int. Cl. G03F 7/00; G01L 19/00

(52) U.S. Cl. CPC G03F 7/70341; G01L 19/0092; G03F 7/70516; G03F 7/70525; G03F 7/7085; G03F 7/70891; G03F 7/70991

(57) ABSTRACT

A gas supply module for a fluid handling system in a lithographic apparatus, the gas supply system including: a humidifier having a humidifier input and a humidifier output; a first conduit configured to guide gas to the humidifier input; a second conduit configured to supply humidified gas to the fluid handling system; a control valve configured to control gas flow in the first conduit and/or the second conduit; a measurement system configured to measure pressure downstream of the control valve and generate a control signal, wherein the control valve is responsive to the control signal to maintain a constant pressure in the respective first conduit and/or second conduit.

### CROSS-REFERENCE TO RELATED APPLICATIONS

This application claims priority of EP Application Serial No. 23156328.9 which was filed on 13 Feb. 2023 and which is incorporated herein in its entirety by reference.

### FIELD

The present invention relates to a gas supply module, a fluid handling system, lithographic apparatus and a device manufacturing method.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer). Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction.

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Further improvements in the resolution of smaller features may be achieved by providing an immersion fluid having a relatively high refractive index, such as water, on the substrate during exposure. The effect of the immersion fluid is to enable imaging of smaller features since the exposure radiation will have a shorter wavelength in the fluid than in gas. The effect of the immersion fluid may also be regarded as increasing the effective numerical aperture (NA) of the system and also increasing the depth of focus.

The immersion fluid may be confined to a localized area between the projection system of the lithographic apparatus and the substrate by a fluid handling structure.

In an immersion lithography apparatus, gas flows may be used to control the immersion fluid. For example, gas knives may be used to confine immersion liquid to a space between the final element of the projection system and the substrate or substrate support. The effectiveness of a gas knife may be dependent on accurate control of the gas flow. Control of gas flows has conventionally used mass flow controllers or mass flow meters. However, it has been discovered that mass flow controllers and mass flow meters are subject to drift and lose accuracy with time. Therefore, mass flow controllers and mass flow meters used in lithography apparatus have to be replaced and/or recalibrated periodically in order to maintain a desired level of accuracy of gas flows in the apparatus.

### SUMMARY

It is an object of the present invention to provide a gas flow control system that has improved long-term stability.

According to a first aspect of the invention, there is provided a gas supply module for a fluid handling system in a lithographic apparatus, the gas supply system comprising:
a humidifier having a humidifier input and a humidifier output;
a first conduit configured to guide gas to the humidifier input;
a second conduit configured to supply humidified gas to the fluid handling system;
a control valve configured to control gas flow in one of the first conduit and the second conduit;
a measurement system configured to measure pressure downstream of the control valve and generate a control signal;
wherein the control valve is responsive to the control signal to maintain a constant pressure in the one of the first conduit and the second conduit.

According to a second aspect of the invention, there is provided a gas supply module for a fluid handling system in a lithographic apparatus, the gas supply system comprising:
a humidifier having a humidifier input and a humidifier output;
a first conduit configured to guide gas to the humidifier input;
a second conduit configured to supply humidified gas to the fluid handling system;
a control valve configured to control gas flow in one of the first conduit and the second conduit;
a feedback system connected to a sensor downstream of the control valve and configured to maintain a constant flow in the second conduit.

According to a third aspect of the invention, there is provided a lithographic apparatus including the gas supply module.

According to a fourth aspect of the invention, there is provided a device manufacturing method comprising:
confining a liquid to a space between a projection system and a substrate using a gas seal supplied with gas from a gas supply module;
projecting a patterned beam of radiation through the liquid to the substrate using the projection system;
measuring the pressure at a predetermined location in the gas supply module; and
controlling a gas flow in the gas supply module upstream of the predetermined location to maintain a predetermined gas flow rate in the gas seal.

Further embodiments, features and advantages of the present invention, as well as the structure and operation of the various embodiments, features and advantages of the present invention, are described in detail below with reference to the accompanying drawings.

### DESCRIPTION OF THE DRAWINGS

Embodiments of the invention will now be described, by way of example only, with reference to the accompanying schematic drawings, in which corresponding reference symbols indicate corresponding parts, and in which:

FIG. 1 depicts the schematic overview of the lithographic apparatus;

FIGS. 2a, 2b, 2c and 2d each depict, in cross section, two different versions of a fluid handling system with different features illustrated on the left hand side and the right hand side of each version, which may extend around the complete circumference;

FIG. 3 depicts, in cross-section an immersion system for use in a lithographic apparatus;

FIGS. 4a and b depict schematically a humidifying apparatus;

FIG. 5 is a schematic diagram of a gas supply module of an embodiment of the invention.

FIG. 6 is a graph of pressure versus flow in a gas supply module according to an embodiment of the invention.

The features shown in the figures are not necessarily to scale, and the size and/or arrangement depicted is not limiting. It will be understood that the figures include optional features which may not be essential to the invention. Furthermore, not all of the features of the apparatus are depicted in each of the figures, and the figures may only show some of the components relevant for describing a particular feature.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

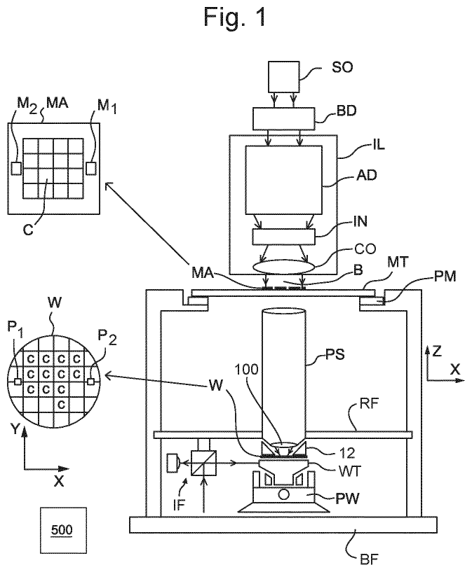

FIG. 1 schematically depicts a lithographic apparatus. The lithographic apparatus includes an illumination system (also referred to as illuminator) IL configured to condition a radiation beam B (e.g., UV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate table) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W. A controller 500 controls the overall operation of the apparatus. Controller 500 may be a centralised control system or a system of multiple separate sub-controllers within various sub-systems of the lithographic apparatus.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus is of a type wherein at least a portion of the substrate W may be covered by an immersion liquid having a relatively high refractive index, e.g., water, so as to fill an immersion space 11 between the projection system PS and the substrate W-which is also referred to as immersion lithography. More information on immersion techniques is given in U.S. Pat. No. 6,952,253, which is incorporated herein by reference.

The lithographic apparatus may be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in figures). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

Immersion techniques have been introduced into lithographic systems to enable improved resolution of smaller features. In an immersion lithographic apparatus, a liquid layer of immersion liquid having a relatively high refractive index is interposed in the immersion space 11 between a projection system PS of the apparatus (through which the patterned beam is projected towards the substrate W) and the substrate W. The immersion liquid covers at least the part of the substrate W under a final element of the projection system PS. Thus, at least the portion of the substrate W undergoing exposure is immersed in the immersion liquid.

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space 11 as immersion liquid. Other liquids with a high refractive index can be used besides water as the immersion liquid, for example: a hydrocarbon, such as a fluorohydrocarbon; and/or an aqueous solution. Further, other fluids besides liquid have been envisaged for use in immersion lithography.

In this specification, reference will be made in the description to localized immersion in which the immersion liquid is confined, in use, to the immersion space 11 between the final element 100 and a surface facing the final element 100. The facing surface is a surface of substrate W or a surface of the supporting stage (or substrate support WT) that is co-planar with the surface of the substrate W. (Please note that reference in the following text to surface of the substrate W also refers in addition or in the alternative to the surface of the substrate support WT, unless expressly stated otherwise; and vice versa). A fluid handling structure 12 present between the projection system PS and the substrate support WT is used to confine the immersion liquid to the immersion space 11. The immersion space 11 filled by the immersion liquid is smaller in plan than the top surface of the substrate W and the immersion space 11 remains substantially stationary relative to the projection system PS while the substrate W and substrate support WT move underneath.

Other immersion systems have been envisaged such as an unconfined immersion system (a so-called ‘All Wet’ immersion system) and a bath immersion system. In an unconfined immersion system, the immersion liquid covers more than the surface under the final element 100. The liquid outside the immersion space 11 is present as a thin liquid film. The liquid may cover the whole surface of the substrate W or even the substrate W and the substrate support WT co-planar with the substrate W. In a bath type system, the substrate W is fully immersed in a bath of immersion liquid. The fluid handling structure 12 is a structure which supplies the immersion liquid to the immersion space 11, removes the immersion liquid from the immersion space 11 and thereby confines the immersion liquid to the immersion space 11. It includes features which are a part of a fluid supply system. The arrangement disclosed in PCT patent application publication no. WO 99/49504 is an early fluid handling structure comprising pipes which either supply or recover the immersion liquid from the immersion space 11 and which operate depending on the relative motion of the stage beneath the projection system PS. In more recent designs, the fluid handling structure extends along at least a part of a boundary of the immersion space 11 between the final element 100 of the projection system PS and the substrate support WT or substrate W, so as to in part define the immersion space 11.

The fluid handing structure 12 may have a selection of different functions. Each function may be derived from a corresponding feature that enables the fluid handling structure 12 to achieve that function. The fluid handling structure 12 may be referred to by a number of different terms, each referring to a function, such as barrier member, seal member, fluid supply system, fluid removal system, liquid confinement structure, etc..

Immersion liquid can be used as the immersion fluid. In that case the fluid handling structure 12 may be a liquid handling system. In reference to the aforementioned description, reference in this paragraph to a feature defined with respect to fluid may be understood to include a feature defined with respect to liquid.

A lithographic apparatus has a projection system PS. During exposure of a substrate W, the projection system PS projects a beam of patterned radiation onto the substrate W. To reach the substrate W, the path of the radiation beam B passes from the projection system PS through the immersion liquid confined by the fluid handling structure 12 between the projection system PS and the substrate W. The projection system PS has a lens element, the last in the path of the beam, which is in contact with the immersion liquid. This lens element which is in contact with the immersion liquid may be referred to as ‘the last lens element’ or “the final element”. The final element 100 is at least partly surrounded by the fluid handling structure 12. The fluid handling structure 12 may confine the immersion liquid under the final element 100 and above the facing surface.

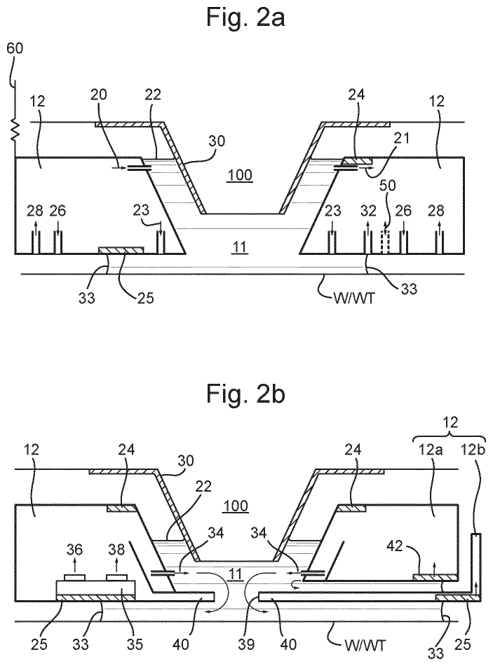

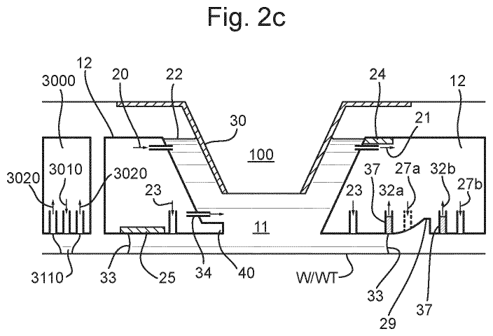

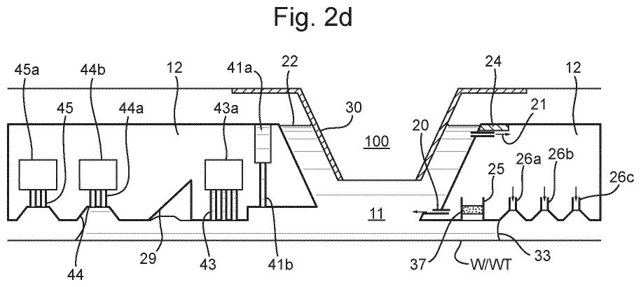

FIGS. 2a, 2b, 2c and 2d show different features which may be present in variations of a fluid handling system. The designs may share some of the same features as FIGS. 2a, 2b, 2c and 2d unless described differently. The features described herein may be selected individually or in combination as shown or as required. The figures depict different versions of a fluid handling system with different features illustrated on the left hand side and the right hand side, which may extend around the complete circumference. Thus, for example, the fluid handling system may have the same features extending around the complete circumference. For example, the fluid handling system may have only the features of the left hand side of FIG. 2a, or the right hand side of FIG. 2a, or the left hand side of FIG. 2b, or the right hand side of FIG. 2b, or the left hand side of 2c, or the right hand side of 2c, or the left hand side of 2d, or the right hand side of 2d. Alternatively, the fluid handling system may be provided with any combination of features from these figures at different locations around the circumference. The fluid handling system may comprise the fluid handling structure 12 as described in the variations below.

FIG. 2a shows a fluid handling structure 12 around the bottom surface of the final element 100. The final element 100 has an inverted frusto-conical shape. The frusto-conical shape having a planar bottom surface and a conical surface. The frusto-conical shape protrudes from a planar surface and having a bottom planar surface. The bottom planar surface is the optically active portion of the bottom surface of the final element 100, through which the radiation beam B may pass. The final element 100 may have a coating 30. The fluid handling structure 12 surrounds at least part of the frusto-conical shape. The fluid handling structure 12 has an inner-surface which faces towards the conical surface of the frusto-conical shape. The inner-surface and the conical surface may have complementary shapes. A top surface of the fluid handling structure 12 may be substantially planar. The fluid handling structure 12 may fit around the frusto-conical shape of the final element 100. A bottom surface of the fluid handling structure 12 may be substantially planar and in use the bottom surface may be parallel with the facing surface of the substrate support WT and/or substrate W. Thus, the bottom surface of the fluid handling structure 12 may be referred to as a surface facing the surface of the substrate W. The distance between the bottom surface and the facing surface may be in the range of 20 to 500 micrometers, desirably in the range of 70 to 200 micrometers.

The fluid handling structure 12 extends closer to the facing surface of the substrate W and substrate support WT than the final element 100. The immersion space 11 is therefore defined between the inner surface of the fluid handling structure 12, the planar surface of the frusto-conical portion and the facing surface. During use, the immersion space 11 is filled with immersion liquid. The immersion liquid fills at least part of a buffer space between the complementary surfaces between the final element 100 and the fluid handling structure 12, e.g. at least part of the space between the complementary inner-surface and the conical surface.

The immersion liquid is supplied to the immersion space 11 through an opening formed in a surface of the fluid handling structure 12. The immersion liquid may be supplied through a supply opening 20 in the inner-surface of the fluid handling structure 12. Alternatively or additionally, the immersion liquid is supplied from an under supply opening 23 formed in the bottom surface of the fluid handling structure 12. The under supply opening 23 may surround the path of the radiation beam B and it may be formed of a series of openings in an array or a single slit. The immersion liquid is supplied to fill the immersion space 11 so that flow through the immersion space 11 under the projection system PS is laminar. The supply of the immersion liquid from the under supply opening 23 additionally prevents the ingress of bubbles into the immersion space 11. This supply of the immersion liquid may function as a liquid seal.

The immersion liquid may be recovered from a recovery opening 21 formed in the inner-surface. The recovery of the immersion liquid through the recovery opening 21 may be by application of an under-pressure; the recovery through the recovery opening 21 as a consequence of the velocity of the immersion liquid flow through the immersion space 11; or the recovery may be as a consequence of both. The recovery opening 21 may be located on the opposite side of the supply opening 20, when viewed in plan. Additionally or alternatively, the immersion liquid may be recovered through an overflow recovery 24 located on the top surface of the fluid handling structure 12. The supply opening 20 and recovery opening 21 can have their function swapped (i.e. the flow direction of liquid is reversed). This allows the direction of flow to be changed depending upon the relative motion of the fluid handling structure 12 and substrate W.

Additionally or alternatively, immersion liquid may be recovered from under the fluid handling structure 12 through a recovery opening 25 formed in its bottom surface. The recovery opening 25 may serve to hold a meniscus 33 of the immersion liquid to the fluid handling structure 12. The meniscus 33 forms between the fluid handling structure 12 and the facing surface and it serves as border between the liquid space and the gaseous external environment. The recovery opening 25 may be a porous plate which may recover the immersion liquid in a substantially single phase flow. The recovery opening in the bottom surface may be a series of pinning openings 32 through which the immersion liquid is recovered. The pinning openings 32 may recover the immersion liquid in a two phase flow.

Optionally radially outward, with respect to the inner-surface of the fluid handling structure 12, is a gas knife opening 26. Gas may be supplied through the gas knife opening 26 at elevated speed to assist liquid confinement of the immersion liquid in the immersion space 11. The supplied gas may be humidified and it may contain substantially carbon dioxide. Radially outward of the gas knife opening 26 is a gas recovery opening 28 for recovering the gas supplied through the gas knife opening 26.

Further openings, for example open to atmosphere or to a gas source or to a vacuum, may be present in the bottom surface of the fluid handling structure 12, i.e. in the surface of the fluid handling structure 12 facing the substrate W. An example of such an optional further opening 50 is shown in dashed lines on the right hand side of FIG. 2a. As shown, the further opening 50 may be a supply or extraction member, which is indicated by the double-headed arrow. For example, if configured as a supply, the further opening 50 may be connected to a liquid supply or a gas supply as with any of the supply members. Alternatively, if configured as an extraction, the further opening 50 may be used to extract fluid, and may for example, be connected to atmosphere or to a gas source or to a vacuum. For example, the at least one further opening 50 may be present between gas knife opening 26 and gas recovery opening 28, and/or between pinning openings 32 and gas knife opening 26.

The two different versions of the fluid handling structure 12 of the left and right sides of FIG. 2a pin the meniscus 33. The version of the fluid handling structure 12 on the right hand side of FIG. 2a may pin the meniscus 33 at a position that is substantially fixed with respect to the final element 100, due to the fixed position of the pinning opening 32. The version of the fluid handling structure 12 on the left hand side of FIG. 2a may pin the meniscus 33 below the recovery opening 25, and thus the meniscus 33 may move along the length and/or width of the recovery opening 25. For the radiation beam B to be directed to a full side of the substrate W under exposure, the substrate support WT supporting the substrate W is moved relative to the projection system PS. To maximize the output of substrates W exposed by the lithographic apparatus, the substrate support WT (and so substrate W) is moved as fast as possible. However, there is a critical relative speed (often referred to as a critical scan speed) above which the meniscus 33 between the fluid handling structure 12 and the substrate W becomes unstable. An unstable meniscus 33 has a greater risk of losing immersion liquid, for example in the form of one or more droplets. Furthermore, an unstable meniscus 33 has a greater risk of resulting in the inclusion of gas bubbles in the immersion liquid, especially when the confined immersion liquid crosses the edge of the substrate W.

A droplet present on the surface of the substrate W may apply a thermal load and may be a source of defectivity. The droplet may evaporate leaving a drying stain, it may move transporting contamination such as a particle, it may collide with a larger body of immersion liquid introducing a bubble of gas into the larger body and it may evaporate, applying the thermal heat load to the surface on which it is located. Such a thermal load could be a cause of distortion and/or a source of a positioning error if the surface is associated with positioning of components of the lithographic apparatus relative to the substrate W being imaged. A formation of a droplet on a surface is therefore is undesirable. To avoid formation of such a droplet, the speed of the substrate support WT is thus limited to the critical scan speed at which the meniscus 33 remains stable. This limits the throughput of the lithographic apparatus.

The left hand side of the fluid handling system in FIG. 2a may comprise a spring 60. The spring 60 may be an adjustable passive spring configured to apply a biasing force to the fluid handling structure 12 in the direction of the substrate W. Thus, the spring 60 can be used to control the height of the fluid handling structure 12 above the substrate W. Such adjustable passive springs are described in U.S. Pat. No. 7,199,874 which is herein incorporated by reference in its entirety. Other bias devices may also be appropriate, for example, using an electromagnetic force. Although the spring 60 is shown with the left hand side of FIG. 2a, it is optional and does not need to be included with the other features of the left hand side of FIG. 2a. The spring 60 is not shown on any of the other figures, but could also be included with the other variations of the fluid handling system described in relation to FIG. 2a, 2b, 2c, or 2d.

FIG. 2b shows two different versions of the fluid handling structure 12 on its left side and on its right side, which allow movement of the meniscus 33 with respect to the final element 100. The meniscus 33 may move in the direction of the moving substrate W. This decreases the relative speed between the meniscus 33 and the moving substrate W, which may result in improved stability and a reduced risk of breakdown of the meniscus 33. The speed of the substrate W at which the meniscus 33 breaks down is increased so as to allow faster movement of the substrate W under the projection system PS. Throughput is thus increased.

Features shown in FIG. 2b which are common to FIG. 2a share the same reference numbers. The fluid handling structure 12 has an inner surface which complements the conical surface of the frusto-conical shape. The bottom surface of the fluid handling structure 12 is closer to the facing surface than the bottom planar surface of the frusto-conical shape.

Immersion liquid is supplied to the immersion space 11 through supply openings 34 formed in the inner surface of the fluid handling structure 12. The supply openings 34 are located towards the bottom of the inner surface, perhaps below the bottom surface of the frusto-conical shape. The supply openings 34 are located around the inner surface, spaced apart around the path of the radiation beam B.

Immersion liquid is recovered from the immersion space 11 through recovery openings 25, in the bottom surface of the fluid handling structure 12. As the facing surface moves under the fluid handling structure 12, the meniscus 33 may migrate over the surface of the recovery opening 25 in the same direction as the movement of the facing surface. The recovery openings 25 may be formed of a porous member. The immersion liquid may be recovered in single phase. The immersion liquid may be recovered in a two phase flow. The two phase flow is received in a chamber 35 within the fluid handling structure 12 where it is separated into liquid and gas. The liquid and gas are recovered through separate channels 36, 38 from the chamber 35.

An inner periphery 39 of the bottom surface of fluid handling structure 12 extends into the immersion space 11 away from the inner surface to form a plate 40. The inner periphery 39 forms a small aperture which may be sized to match the shape and size of the radiation beam B. The plate 40 may serve to isolate the immersion liquid at either side of it. The supplied immersion liquid flows inwards towards the aperture, through the inner aperture and then under the plate 40 radially outwardly towards the surrounding the recovery openings 25.

The fluid handling structure 12 may be in two parts as shown on the right hand side of FIG. 2b: an inner part 12a and an outer part 12b. The inner part 12a and the outer part 12b may move relatively to each other, mainly in a plane parallel to facing surface. The inner part 12a may have the supply openings 34 and it may have the overflow recovery 24. The outer part 12b may have the plate 40 and the recovery opening 25. The inner part 12a may have an intermediate recovery 42 for recovering the immersion liquid which flows between the inner part 12a and the outer part 12b.

The two different versions of the fluid handling structure of FIG. 2b thus allow for movement of the meniscus 33 in the same direction as the substrate W, enabling faster scan speeds and increased throughput of the lithographic apparatus. However, the migration speed of meniscus 33 over the surface of the recovery opening 25 in the fluid handling structure 12 of the left side of FIG. 2b may be slow. The fluid handling structure 12 of the right side of FIG. 2b allows for quicker movement of the meniscus 33, by moving the outer part 12b with respect to the inner part 12a and the final element 100. However, it may be difficult to control the intermediate recovery 42 so as to ensure that enough immersion liquid is provided between the inner part 12a and the outer part 12b to prevent contact therebetween.

FIG. 2c shows two different versions of the fluid handling structure 12 on its left side and on its right side, which may be used to pin the meniscus 33 of the immersion liquid to the fluid handling structure 12 as described above in relation to FIGS. 2a and/or 2b. Features shown in FIG. 2c which are common to FIGS. 2a and/or 2b share the same reference numbers.

The fluid handling structure 12 has an inner surface which compliments the conical surface of the frusto-chronical shape. The bottom surface of the fluid handling structure 12 is closer to the facing surface than the bottom planar surface of the frusto-chronical shape. Immersion liquid is supplied to the immersion space 11 delivered through an opening formed in a surface of the fluid handling structure 12. The immersion liquid may be supplied through a supply opening 34 in the inner surface of the fluid structure 12. Alternatively or additionally, the immersion liquid may be supplied through a supply opening 20 in the inner surface of the fluid structure 12. Alternatively or additionally, the immersion liquid is supplied through the under supply opening 23. The immersion liquid may be recovered via an extraction member, for example, via recovery opening 21 formed in the inner-surface and/or overflow recovery 24 and/or one or more openings in a surface of the fluid handling structure 12 as described below.

The two different versions of the fluid handling structure 12 of the left and right sides of FIG. 2c pin the meniscus 33. The version of the fluid handling structure 12 on the right hand side of FIG. 2c may pin the meniscus 33 at a position that is substantially fixed with respect to the final element 100, due to the fixed position of the recovery opening 32a. The version of the fluid handling structure 12 on the left hand side of FIG. 2c may pin the meniscus 33 below the recovery opening 25, and thus the meniscus 33 may move along the length and/or width of the recovery opening 25.

As described above in relation to FIG. 2b, an inner periphery of the bottom surface of fluid handling structure 12 may extends into the immersion space 11 away from the inner surface to form a plate 40 as shown on the left hand side. As described above, this may form a small aperture, and may isolate the immersion liquid at either side and/or cause immersion liquid to flow inwards towards the aperture, through the inner aperture and then under the plate 40 radially outwardly towards the surrounding the recovery openings 25. Although this features is shown on the left hand side in FIG. 2c, it is optional in combination with the other features shown. Preferably, as shown on the left hand side, immersion liquid is supplied to the immersion space 11 through supply openings 34 formed in the inner surface of the fluid handling structure 12. The supply openings 34 are located towards the bottom of the inner surface, perhaps below the bottom surface of the frusto-conical shape. The supply openings 34 are located around the inner surface, spaced apart around the path of the radiation beam B. Alternatively or additionally, the immersion liquid may be supplied through a supply opening 20 in the inner surface of the fluid structure 12. Alternatively or additionally, the immersion liquid is supplied through the under supply opening 23. Although the supply openings 34 are the preferred liquid supply, any combination of supply openings 34, supply openings 20 and/or under supply openings 23 may be provided.

As shown on the left hand side of FIG. 2c, a fluid handling system may comprise the fluid handling structure 12 as described above and a further device 3000. The fluid handling structure 12 may have an extraction member, such as recovery opening 25, and a liquid supply opening, such as the under supply opening 23. It will be understood that the fluid handling structure 12 may comprise any configuration as disclosed in relation to the left hand of FIG. 2a, the right hand side of FIG. 2a, the left hand side of FIG. 2b, the right hand side of FIG. 2b or (as described below) the right hand side of FIG. 2c, in combination with the further device 3000.

The further device 3000 may otherwise be referred to as a droplet catcher. The further device 3000 is provided to reduce occurrence of liquid on the surface of the substrate W after the fluid handling structure 12 has moved over the surface. The further device 3000 may comprise a liquid supply member 3010 and at least one extraction member 3020. The at least one extraction member 3020 may be formed in a shape surrounding the at least one supply member 3010 in plan. The at least one liquid supply member 3010 may be configured to provide a further liquid to a space 3110 between at least a part of the further device 3000 and the surface of the substrate W. The further device 3000 may be configured to recover at least some of the liquid via the at least one extraction member 3020. The further device 3000 may be used to incorporate any liquid left on the surface of the substrate W with the liquid in the space 3110 and then use the further device 3000 to extract the liquid such that the amount of liquid remaining on the surface of the substrate W is reduced.

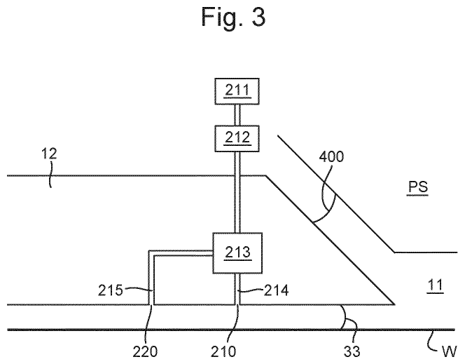

The further device 3000 is shown as a separate device from the fluid handling structure 12 in FIG. 2c. The further device 3000 may be positioned adjacent to the fluid handling structure 12. Alternatively, the further device 3000 may be part of, i.e. integral to, the fluid handling structure 12 (as in FIG. 3d, however, either arrangement can be selected).

The further device 3000 may be configured to provide a liquid to the space 3110 which is separate from the liquid provided by the fluid handling structure 12.

Additionally or alternatively, the fluid handling structure 12 may have the components as shown on the right hand side of FIG. 2c. More specifically, the fluid handling structure 12 may comprise the at least one liquid supply member, two extraction members (e.g., recovery openings 32a and 32b) and two gas supply members (e.g., gas supply openings 24a and 24b) formed on the surface of the fluid handling structure 12. Gas supply opening 24a can be omitted, i.e. is optional. The at least one liquid supply member may be the same as the under supply opening 23 in the bottom surface of the fluid handling structure 12 described above or the supply opening 20 or liquid supply openings 34 formed on the inner surface of the fluid handling structure 12 described in relation to left hand side of FIG. 2b. The liquid supply member, the extraction members and the gas supply members may be formed on the surface of the fluid handling structure 12. Specifically, these components may be formed on a surface of the fluid handling structure 12 facing the substrate W, i.e. the bottom surface of the fluid handling structure 12.

At least one of the two extraction members may comprise a porous material 37 therein. The porous material 37 may be provided within an opening, e.g., recovery opening 32a through which fluid handling structure 12 extracts fluid from below the fluid handling structure 12 and may recover the immersion liquid in a single phase flow. The other of the two extraction members, e.g., recovery opening 32b may recover the immersion fluid as a dual phase extractor. The porous material 37 does not need to be flush with the bottom surface of the fluid handling structure 12.

Specifically, the fluid handling structure 12 may comprise the liquid supply member (e.g., under supply opening 23), with a first extraction member (e.g., recovery opening 32a) radially outwards of the liquid supply member, and a first gas supply member (e.g., gas supply opening 24a) radially outwards of the first extraction member, and the second extraction member (e.g., recovery opening 32b) radially outwards of the first gas supply member, and a second gas supply member (e.g., gas supply opening 24b) radially outwards of the second extraction member. Similar to FIG. 2a, further openings, for example open to atmosphere or to a gas source or to a vacuum, may be present in the bottom surface of the fluid handling structure 12 as described previously (in relation to the fluid handling structure 12).

For example, at least one further opening (not shown) may be provided in the bottom surface of the fluid handling structure 12. The further opening is optional. The further opening may be arranged between the first extraction member (e.g., recovery opening 32a) and the first gas supply member (e.g., gas supply opening 24a) as described in the arrangement above. Alternatively or additionally, the further opening may be arranged between the second extraction member (e.g., recovery opening 32b) and the second gas supply member (e.g., gas supply opening 24b) as described in the arrangement above. The further opening may be the same as further opening 50 described above.

Optionally, the fluid handling structure 12 comprises a recess 29. The recess 29 may be provided between the recovery opening 32a and recovery opening 32b or gas supply opening 24a and recovery opening 32b. The shape of the recess 29 may be uniform around the fluid handling structure 12 and may optionally contain an inclined surface. In the case of the recess 29 provided between the recovery opening 32a and recovery opening 32b, the gas supply opening 24b may be provided on the inclined surface as shown in FIG. 2c. In the case of the recess 29 provided between the supply opening 24a and recovery opening 32b, the gas supply opening 24b may be provided on the inclined surface or a part of the bottom surface of the fluid handling structure 12 which is parallel to the surface of the substrate W. Alternatively, the shape of the recess 29 may vary around the circumference of the fluid handling structure 12. The shape of the recess 29 may be varied to alter the impact of gas supplied from the gas supply members on the fluid below the fluid handling structure 12.

FIG. 2d shows, in its left and right halves, two different versions of the fluid handling structure 12. The fluid handling structure 12 of the left half of FIG. 2d has a liquid injection buffer 41a, which holds a buffer amount of immersion liquid, and liquid injection holes 41 which supply immersion liquid from the liquid injection buffer to the space 11. Outwardly of the liquid injection holes 41 are inner liquid recovery apertures 43 for conducting liquid to an inner recovery buffer 43a which is provided with a porous member. A recess 29 similar to that described relating to FIG. 2c is provided outward of the inner liquid recovery apertures 43. Outward of the recess 29, in the lower face of the fluid handling structure 12 is a gas guiding groove 44 into which open outer recovery holes 44a. The outer recovery holes 44a lead a two-phase recovery flow to outer recovery buffer 44b which is also provided with a porous member. Outermost are gas sealing holes 45 which communicate between a gas sealing buffer volume 45a and the space underneath the fluid handling structure 12 to provide a gas flow to contain the immersion liquid.

The fluid handling structure 12 of the right half of FIG. 2d has a liquid supply opening 20 in the inner inclined face thereof. In the underside of the fluid handling structure 12 there are (from inner side to outer side) an extraction opening 25 provided with a porous member 37; a first gas knife opening 26a, a second gas knife opening 26b and a third gas knife opening 26c. Each of these openings opens into a groove in the underside of the fluid handling structure 12 that provides a buffer volume. The outermost part of the fluid handling structure 12 is stepped so as to provide a greater separation between the fluid handling structure 12 and the substrate W.

FIGS. 2a-2d show examples of different configurations which can be used as part of a fluid handling system. It will be understood that the examples provided above refer to specific extraction members and recovery members, but it is not necessary to use the exact type of extraction member and/or recovery member. In some cases different terminology is used to indicate the position of the member, but the same functional features may be provided. Examples of the extraction member referred to above include recovery opening 21, overflow recover 24, recovery opening 25 (possibly comprising a porous plate and/or the chamber 35), gas recovery opening 28, pinning opening 32, recovery opening 32a, recovery opening 32b and/or the intermediate recovery 42. Examples of the supply member referred to above include supply opening 20, under supply opening 23, gas knife opening 26, gas supply opening 24a, gas supply opening 24b, and/or supply openings 34. In general, an extraction member used to extract/recover fluid, liquid or gas is interchangeable with at least any of the other examples used which extract/recover fluid, liquid or gas respectively. Similarly, a supply member used to supply fluid, liquid or gas is interchangeable with at least any of the other examples used which supply fluid, liquid or gas respectively. The extraction member may extract/recover fluid, liquid or gas from a space by being connected to an under-pressure which draws the fluid, liquid or gas into the extraction member. The supply member may supply fluid, liquid or gas to the space by being connected to a relevant supply.

As previously described, although use of immersion fluid/liquid is beneficial for improving resolution of smaller features on a substrate W, there are also challenges with the use of immersion fluid/liquid relating to defects being introduced on the substrate W.

In general, when immersion liquid is used, droplets of the immersion liquid may be left behind on the surface of the substrate W. The meniscus 33 at the edge of the immersion liquid may collide with any droplets on the surface of the substrate W. When a droplet hits the meniscus 33, gas may be entrapped within the immersion liquid. This results in a bubble in the immersion liquid. Formation of bubbles in the immersion liquid can lead to defects on the substrate W. Droplets that remain on the surface of the substrate W may cause drying spots and/or affect the chemical properties of the resist, also leading to defects.

Very small bubbles of gas may dissolve in the immersion liquid before they reach the exposure area of the immersion space 11. A bubble of carbon dioxide gas typically dissolves faster than a bubble of air. A bubble of CO₂, which has a solubility fifty-five (55) times larger than that of nitrogen and a diffusivity of 0.86 times that of nitrogen, will typically dissolve in a time thirty-seven (37) times shorter than the time for a bubble of the same size of nitrogen to dissolve. Supplying CO₂ adjacent to the meniscus 33 means that a bubble of CO₂ gas will dissolve into the immersion liquid much faster than if other gases with lower diffusivity were used. Therefore, using CO₂ in the fluid handling structure 12 is known to reduce the number of imaging defects thereby allowing higher throughput (e.g., higher speed of the substrate W relative to the fluid handling structure 12) and lower defectivity.

Temperature control in a lithographic apparatus is very important; it is desirable to maintain the temperature of the sensitive parts of the apparatus, e.g. the substrate support WT and the vicinity thereof, at a very precise target temperature. Evaporation of the immersion liquid in two-phase extraction flows is therefore an undesirable thermal load. To minimise this thermal load, it is desirable to use humidified gas in the fluid handling structure 12.

FIG. 3 depicts gas supply arrangements in a fluid handling structure 12. The gas supply system comprises a gas source 211 to provide gas to the at least one gas knife opening 210 and the at least one gas supply opening 220. In an embodiment, the same gas source 211 is used to provide gas to the at least one gas knife opening 210 and the at least one gas supply opening 220, as depicted in FIG. 3. The gas supplied to the gas supply opening 220 may be controlled using a valve (not shown) to redirect gas from the gas knife opening 210 to the gas supply opening 220. In an embodiment, the gas supply system may comprise multiple gas sources to provide gas to the at least one gas knife opening 210 and the at least one gas supply opening 22, respectively.

In an embodiment, the gas supply system comprises a humidifier 212 to control the humidity of the gas provided by at least one of the gas sources. In an embodiment, the gas supplied from the gas source 211 is substantially pure CO₂ gas and the output of the gas supply system is humidified CO₂ gas. In an embodiment, the humidifier 212 increases the humidity of the CO₂ gas provided by at least one of the gas sources. In an embodiment, a humidifier 212 is connected to a gas source 211 as depicted in FIG. 3.

In an embodiment, the fluid handling structure 12 may comprise a reservoir 213. The reservoir 213 may be between the at least one gas supply system and the gas knife opening 210 and the gas supply opening 220. In an embodiment, the reservoir 213 may be a section between the gas supply system and at least one of the gas knife opening 210 and the gas supply opening 220 which has an increased cross-sectional area. In an embodiment, the fluid handling structure 12 may comprise the first path 214 from the reservoir 213 to the gas knife opening 210 and the second path 215 from the reservoir 213 to the gas supply opening 220. In an embodiment, the reservoir 213 may not be provided, i.e. the reservoir 213 is not essential.

Providing a reservoir 213 allows greater control of the gas being emitted from the gas knife opening 210 and/or the gas supply opening 220. For example, the gas may build up in the reservoir 213 and may be more uniformly distributed from the gas knife opening 210 and the gas supply opening 220 along their lengths. Providing a humidifier 212 allows greater control of the gas being emitted from the gas knife opening 210 and/or the gas supply opening 220. For example, the humidity of the gas being supplied to the gas knife opening 210 and/or the gas supply opening 220 can be controlled to affect the humidity of the gas atmosphere adjacent to the meniscus 33.

In an embodiment, the amount of gas supplied to the gas supply opening 220 and/or the gas knife opening 210 is variable. In an embodiment, the gas supplied to the gas supply opening 220 and/or the gas knife opening 210 is dynamically controlled, i.e. the gas supplied can be controlled and varied during use. For example, the gas emitted from either the gas supply opening 220 and/or the gas knife opening 210 may be dynamically controlled depending on certain characteristics of the fluid handling structure 12, including but not limited to, the direction of movement, the speed, the velocity, and/or the location of the fluid handling structure 12.

In an embodiment, the gas knife opening 210 comprises a series of discrete apertures. For example, the gas knife opening 210 may be provided with two discrete apertures, for example each aperture being two sides of a four-sided shape formed by the gas knife opening 210. Alternatively, the gas knife opening 210 may have a single discrete aperture along each side of the four-sided shape formed by the gas knife opening 210. Thus, the gas knife opening 210 may be provided by four discrete apertures. The shape of each aperture is not particularly limited and the gas knife opening 210 may be provided by any number of discrete apertures.

Each aperture may be individually controlled to vary the gas flow rate and/or gas velocity of the gas exiting the different apertures of the gas knife opening 210. At least one of the apertures may be dynamically controlled depending on certain characteristics of the fluid handling structure 12, including but not limited to, the direction of movement, the speed, the velocity, and/or the location of the fluid handling structure 12. For example, when in use, apertures of the gas knife opening 210 on the advancing side of the fluid handling structure 12 may be controlled to have gas exiting at a lower gas flow rate and/or gas velocity than the flow rate and/or gas velocity respectively of gas exiting apertures of the gas knife opening 210 on the receding side of the fluid handling structure 12.

Similarly, the gas supply opening 220 may additionally or alternatively comprise a series of discrete apertures as herein described, which may be individually controlled as herein described.

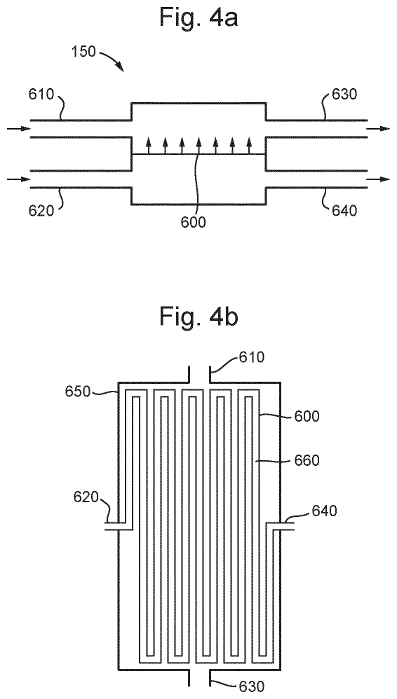

FIGS. 4a and 4b illustrate humidifying apparatus 150 which may be used with the gas supply system of FIG. 3.

The basic arrangement of the humidifying apparatus 150 is illustrated in FIG. 4a and a more complex structure is illustrated in FIG. 4b which works on the same principles. In FIG. 4a the humidifying apparatus comprises a membrane 600 which behaves as if impermeable to the liquid with which the gas is to be humidified (usually (ultra-pure) water) and permeable to the vapour of that liquid. It should be possible to pressurize the liquid side of the membrane (though this is not necessary with a hydrophilic membrane as described below) and no liquid should pass through the membrane. One can also pressurize the gas side (at least using air or its components like nitrogen, oxygen etc.) and no gas bubbles will pass through the membrane either. In some cases, the liquid wets the membrane material and then evaporates. In other cases, the membrane 600 allows only vapour of the liquid to pass and the liquid molecules can leave the membrane 600 as they go into gas. A little gas may dissolve into the liquid from the gas side of the membrane 600 but no bubbles form in the liquid. Thus, the membrane 600 can be seen as permeable to vapour of the liquid.

A first conduit 610 guides a gas to be humidified to one side of the membrane 600 and a second conduit 620 guides the liquid to humidify the gas to the other side of the membrane 600. As the gas is present on one side of the membrane 600 and the liquid on the other side of the membrane 600 vapour from the liquid will pass through the membrane 600 and humidify the gas. Preferably a flow of gas is provided past the membrane 600 so that a third conduit 630 is provided for guiding the gas which has been humidified away from the membrane 600 and a fourth conduit 640 is provided for guiding liquid away from the other side of the membrane 600.

A similar humidifying apparatus to this is disclosed in WO 2005/010619 and much of what is said in that application is applicable here in particular regarding the shape of the membrane 600, how it is connected, etc., However, in contrast to the disclosure of WO 2005/010619, the membrane 600 in an embodiment of the present invention may be provided with a liquidphilic surface. In other words, the liquid on the one side of the membrane 600 has a contact angle with the membrane 600 of less than 90°, preferably less than 70°, more preferably less than 60°, yet more preferably less than 50° and most preferably less than 30° or even less than 20°.

One suitable class of material for use as the membrane 600 is polymerized fluorinated sulfonic acid copolymers which are synthetic ionic polymers. The sulfonic acid groups are chemically active, but they are fixed within the polymer matrix. One such material has the following chemical formula:

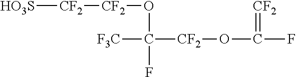

The hydrophilic nature of the membrane could be provided, for example, through a coating (on one or both sides of the membrane 600) and/or through applying an electrical potential to the membrane 600, for example. These types of membranes have previously been used in steam purification systems such as those sold by Rasirc of San Diego, California, US under the trade name Intaeger.

The advantage of such a membrane is that a low pressure of liquid can be used on the liquid side of the membrane and there is better efficiency of gas side evaporation of the liquid, i.e. there is greater mass transfer across the membrane. Furthermore, for liquidphilic membranes, it is not necessary to pressurize the liquid so that the actual hardware has considerably lower pressure drop off (factor of 10) compared to liquidphobic membranes.

It is advantageous to maximize the surface area of membrane 600 and a preferred embodiment is where the membrane 600 is a hollow fibre with the liquid passing through the inside of the hollow fibre and the gas passing over the outside of the hollow fibre (though vice versa could be true also). One such embodiment is illustrated in FIG. 4b in which the liquid is provided through hollow fibre 660 which is comprised of the membrane 600. Only one fibre is illustrated in FIG. 4b but of course the second conduit 620 could be connected to several fibres in parallel.

In the embodiment of FIG. 4b the gas enters a housing 650 which surrounds the hollow fibres 660 and is passed over the hollow fibres 660 after being guided by conduit 610 into the housing and then, once humidified, the gas is guided out of the housing by third conduit 630.

In order to provide the flow of gas and flow of liquid, a liquid provider and gas provider are necessary. These could take the form, for example, of a pump providing the liquid and a compressed gas source.

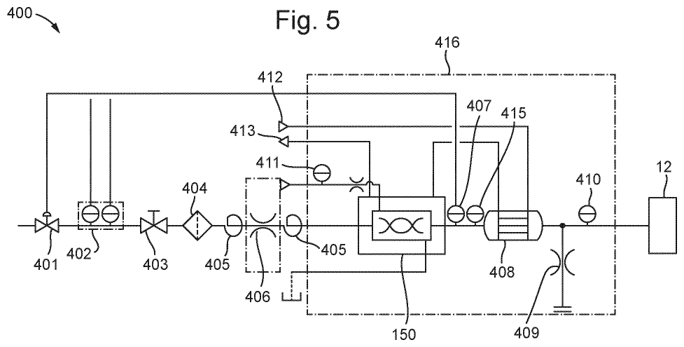

A gas supply module 400 of an embodiment of the invention is schematically depicted in FIG. 5. Gas, e.g. carbon dioxide, is supplied from a gas source (not shown) to an input control valve 401 which regulates flow of gas into the supply module 400. As will be discussed further in more detail, the flow of gas through the gas supply module 400 is regulated on the basis of a pressure measurement at a predetermined point within the gas supply module 400. The present inventors have determined that a reliable relationship between pressure and gas flow can be determined so that a pressure sensor, which is not as subject to long term drift as a mass flow controller or mass flow meter, can be used to monitor and control flow of gas through the gas supply module 400. Depending on the exact arrangement of the gas supply module 400, various different locations for a pressure sensor may be suitable. Desirably, the location of the pressure sensor is chosen so that there is a substantially linear relationship between pressure and flow, at least over a range of flow rates of interest. Desirably, the pressure sensor is downstream of any variable elements in the gas supply module 400. Desirably, the pressure sensor is downstream of a humidifier 150. Desirably, the pressure sensor is downstream of a temperature conditioner 408.

The relationship between pressure and flow rate may be determined via theoretical calculations or by empirical calibration. In many cases, minor variations in manufacturing will affect the relationship between pressure and flow so that to achieve a desired level of accuracy, it may be desirable to calibrate each gas supply module 400 before installation in the lithographic apparatus. However, such variations are generally stable over time so that subsequent re-calibration is unlikely to be necessary except in the event of substantial modifications to the lithographic apparatus or replacement of parts within the gas supply module 400.

Referring again to FIG. 5, after the control valve 401, safety sensors 402 are provided to monitor the gas pressure in the gas supply module 400. There may be two safety sensors 402. Safety sensors 402 may monitor whether the pressure in the gas supply module 400 remains within an acceptable range and alert a user or shut down the apparatus in the event of a dangerous excursion. A manual shut-off valve 403 is provided to shut off gas supply manually if desired. A filter 404 is provided to ensure that no particulates or other contaminants enter the lithographic apparatus.

Filtered gas output by filter 404 passes through humidifier 150 and temperature conditioner 408 before being supplied to the fluid handling structure 12, in particular to form a gas knife. It is desirable that the humidifier 150 and temperature conditioner 408 are as close as convenient to the fluid handling structure 12, whereas components 401 to 404 may be elsewhere, even outside the main part of the lithographic apparatus. Therefore, hoses 405 may be used to connect filter 404 to humidifier 150. Hoses 405 may be relatively long, e.g. several meters, and may therefore form an effective flow resistance, indicated in the diagram as 406. Humidifier 150 and temperature conditioner 408 may be included in a point of use module 416 that is physically close to the point where the conditioned gas is to be used.

A pressure sensor 407 (an example of a measurement system) is provided in the outlet of humidifier 150 and is connected in a feedback loop to control valve 401 to regulate the flow of gas into the gas supply module 400, such that a constant pressure, corresponding to a desired flow rate, is maintained at the output of humidifier 150. An additional sensor 415 may be provided at this location as well, e.g. for safety or to provide redundancy. A further pressure sensor 410 is shown between the output of temperature conditioner 408 and input to the fluid handling structure 12. This is an alternative location for a pressure sensor to provide feedback control to the control valve 401.

Alternatively, the flow of gas through the gas supply module 400 may be regulated by a mass flow controller (another example of a measurement system) within the gas supply module 400. In such an arrangement, the mass flow controller replaces control valve 401 and the feedback loop from pressure sensor 407 may be omitted. A mass flow controller may have an internal feedback loop. In general a mass flow controller is a mass flow meter (i.e. a sensor) combined with a control valve and feedback electronics between the sensor and the control valve.

In an embodiment, temperature conditioner 408 comprises a heat exchanger which is provided with temperature-controlled fluid via an inlet 412. The temperature controlled fluid may be, for example, from the same supply as is used to control the temperature of the projection system PS. Fluid that has passed through temperature conditioner 408 may conveniently be provided as input to humidifier 150 since the temperature of the fluid used to humidify the gas is not as critical as some other parts of the apparatus, e.g. the projection system PS. The temperature of the fluid used to humidify the gas should be high enough to enable a sufficient rate of evaporation of the fluid in the humidifier 150. An outlet 413 returns the fluid for reconditioning.

Flow restriction 409 leads to a sampling point that may be used for testing purposes, e.g. measurement of humidity using an external tool. The sampling point is normally capped and the flow restriction 409 is provided to limit gas leak in the event that the cap is improperly installed.

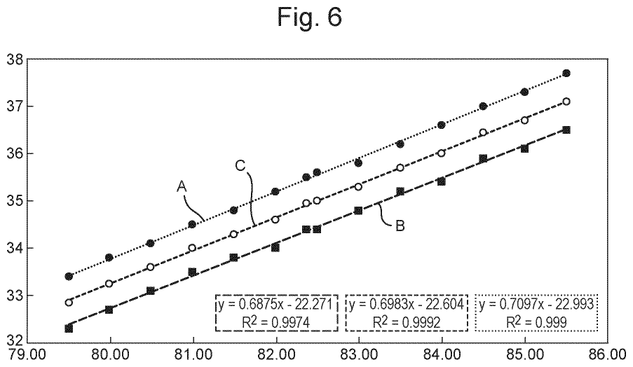

As mentioned above, to effect control of the gas flow on the basis of a measured pressure, it is desirable to know accurately the relationship between pressure and flow. FIG. 6 represents pressure and flow measurements taken in an experimental set up corresponding to an embodiment of the present invention. Pressure is given on the x-axis in arbitrary units and flow on the y-axis in arbitrary units. Pressure measurements were taken using pressure sensors 407 (line A, solid circles) and 415 (line B, solid squares) and correlated to flow measurements at the output of a gas knife. Pressure sensors 407, 415 are located between the humidifier and the heat exchanger but could also be located elsewhere in the gas supply module. It will be seen that pressures measured by both sensors have very linear relationships (R²=0.000 and 0.9974) to flow and by averaging the two pressure readings (line C, open circles) an even more linear measurement (R²=0.9992) can be obtained.

A gas supply module 400 as described above may also be used in a further device 3000 which acts as a droplet removal system (or droplet catcher) as described above in FIG. 2c.

The present invention may provide a lithographic apparatus. The lithographic apparatus may have any/all of the other features or components of the lithographic apparatus as described above. For example, the lithographic apparatus may optionally comprise at least one or more of a source SO, an illumination system IL, a projection system PS, a substrate support WT, etc.

Specifically, the lithographic apparatus may comprise the projection system PS configured to project the radiation beam B towards the region of the surface of a substrate W. The lithographic apparatus may further comprise the fluid handling system as described in any of the above embodiments in FIGS. 2a-d and variations.

The lithographic apparatus may comprise an actuator (not shown) configured to move the substrate W relative to the fluid handling system. Thus, the actuator may be used to control the position of the substrate W (or alternatively, the position of the fluid handling system). The actuator could be, or could comprise, the substrate support (e.g., a substrate table) WT and/or a substrate holder constructed to hold the substrate W and/or the second positioner PW configured to accurately position the substrate support WT.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use ambient (non-vacuum) conditions.

Although specific reference may have been made above to the use of embodiments of the invention in the context of optical lithography, it will be appreciated that the invention, where the context allows, is not limited to optical lithography.

Embodiments include the following numbered clauses:

1. A gas supply module for a fluid handling system in a lithographic apparatus, the gas supply system comprising:
a humidifier having a humidifier input and a humidifier output;
a first conduit configured to guide gas to the humidifier input;
a second conduit configured to supply humidified gas to the fluid handling system;
a control valve configured to control gas flow in one of the first conduit and the second conduit;
a measurement system configured to measure pressure downstream of the control valve and generate a control signal;
wherein the control valve is responsive to the control signal to maintain a constant pressure in the one of the first conduit and the second conduit.
   2. The gas supply module according to clause 1, wherein the control valve is provided in the first conduit.
   3. The gas supply module according to clause 1, wherein the control valve is provided in the second conduit.
   4. The gas supply module according to clause 1 or 2, wherein the measurement system comprises a pressure sensor configured to measure the pressure in the first conduit.
   5. The gas supply module according to clause 1, 2 or 3, wherein the measurement system comprises a pressure sensor configured to measure the pressure in the second conduit.
   6. The gas supply module according to any one of the preceding clauses, further comprising a heat exchanger downstream of the humidifier configured to condition the temperature of the humidified gas.
   7. The gas supply module according to clause 6, further comprising a liquid supply system configured to supply liquid to the humidifier and the heat exchanger.
   8. The gas supply module according to any one of the preceding clauses, wherein the control valve is configured to maintain a pressure in the one of the first conduit and the second conduit such that the gas flow rate in the second conduit is a predetermined rate, the predetermined rate being greater than 50 nlpm, desirably greater than 75 nlpm.
   9. A fluid handling system for a lithographic apparatus, the fluid handling system comprising a gas supply module according to any one of the preceding clauses; wherein the gas supply module is configured to supply gas to a gas seal configured to confine fluid in a region.
   10. A lithographic apparatus comprising a fluid handling system according to clause 9.
   11. A device manufacturing method comprising:
confining a liquid to a space between a projection system and a substrate using a gas seal supplied with gas from a gas supply module;
projecting a patterned beam of radiation through the liquid to the substrate using the projection system;
measuring the pressure at a predetermined location in the gas supply module; and
controlling a gas flow in the gas supply module upstream of the predetermined location to maintain a predetermined gas flow rate in the gas seal.
   12. A method of calibrating a gas supply module for a fluid handling system in a lithographic apparatus, the method comprising:
measuring the pressure at a predetermined location in the gas supply module;
measuring the gas flow rate output by the gas supply module; and
determining a target pressure at the predetermined location to provide a desired gas flow rate.
   13. A method according to clause 12 wherein the calibration is performed while the gas supply module is fluidly connected to the fluid handling system.
   14. A gas supply module for a fluid handling system in a lithographic apparatus, the gas supply system comprising:
a humidifier having a humidifier input and a humidifier output;
a first conduit configured to guide gas to the humidifier input;
a second conduit configured to supply humidified gas to the fluid handling system;
a control valve configured to control gas flow in one of the first conduit and the second conduit;
a feedback system connected to a sensor downstream of the control valve and configured to maintain a constant flow in the second conduit.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A gas supply module for a fluid handling system in a lithographic apparatus, the gas supply system comprising:
a humidifier having a humidifier input and a humidifier output;
a first conduit configured to guide gas to the humidifier input;
a second conduit configured to supply humidified gas to the fluid handling system;
a control valve configured to control gas flow in the first conduit and/or the second conduit;
a measurement system configured to measure pressure downstream of the control valve and generate a control signal,
wherein the control valve is responsive to the control signal to maintain a constant pressure in the respective first conduit and/or second conduit.

2. The gas supply module according to claim 1, wherein the control valve is provided in the first conduit.

3. The gas supply module according to claim 1, wherein the control valve is provided in the second conduit.

4. The gas supply module according to claim 1, wherein the measurement system comprises a pressure sensor configured to measure the pressure in the first conduit.

5. The gas supply module according to claim 1, wherein the measurement system comprises a pressure sensor configured to measure the pressure in the second conduit.

6. The gas supply module according to claim 1, further comprising a heat exchanger downstream of the humidifier configured to condition the temperature of the humidified gas.

7. The gas supply module according to claim 6, further comprising a liquid supply system configured to supply liquid to the humidifier and the heat exchanger.

8. The gas supply module according to claim 1, wherein the control valve is configured to maintain a pressure in the respective first conduit and/or second conduit such that the gas flow rate in the second conduit is a predetermined rate, the predetermined rate being greater than 50 nlpm.

9. A fluid handling system for a lithographic apparatus, the fluid handling system comprising the gas supply module according to claim 1, wherein the gas supply module is configured to supply gas to a gas seal configured to confine fluid in a region.

10. A lithographic apparatus comprising the fluid handling system according to claim 9.

11. A device manufacturing method comprising:
confining a liquid to a space between a projection system and a substrate using a gas seal supplied with gas from a gas supply module;
projecting a patterned beam of radiation through the liquid to the substrate using the projection system;
measuring the pressure at a predetermined location in the gas supply module; and
controlling, by a control valve and based on the measured pressure, a gas flow in the gas supply module upstream of the predetermined location to maintain a predetermined gas flow rate in the gas seal.

12. A method of calibrating a gas supply module for a fluid handling system in a lithographic apparatus, the method comprising:
measuring the pressure at a predetermined location in the gas supply module;
measuring the gas flow rate output by the gas supply module; and
determining a target pressure at the predetermined location to provide a desired gas flow rate.

13. The method according to claim 12, wherein the calibration is performed while the gas supply module is fluidly connected to the fluid handling system.

14. A gas supply module for a fluid handling system in a lithographic apparatus, the gas supply system comprising:
a humidifier having a humidifier input and a humidifier output;
a first conduit configured to guide gas to the humidifier input;
a second conduit configured to supply humidified gas to the fluid handling system;
a control valve configured to control gas flow in the first conduit and/or the second conduit; and
a feedback system connected to a sensor downstream of the control valve and configured to maintain a constant flow in the second conduit.

15. The gas supply module according to claim 14, wherein the control valve is provided in the first conduit.

16. The gas supply module according to claim 14, wherein the control valve is provided in the second conduit.

17. The gas supply module according to claim 14, wherein the sensor comprises a pressure sensor configured to measure pressure of the gas flow.

18. The gas supply module according to claim 14, further comprising a heat exchanger downstream of the humidifier configured to condition the temperature of the humidified gas.

19. A fluid handling system for a lithographic apparatus, the fluid handling system comprising the gas supply module according to claim 14, wherein the gas supply module is configured to supply gas to a gas seal configured to confine fluid in a region.

20. A lithographic apparatus comprising the fluid handling system according to claim 19.
